(19) United States
(12) Patent Application Publication
(10) Pub. No.: US 2006/0084248 A1
(43) Pub. Date: Apr. 20, 2006

(54) Methods of optimization of implant conditions to minimize channeling and structures formed thereby

(76) Inventors: Pushkar Ranade, Hillsboro, OR (US); Aaron D. Lilak, Hillsboro, OR (US); Sanjay Natarajan, Portland, OR (US); Gerard T. Zietz, Banks, OR (US); Jose Maiz, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/966,200

(22) Filed: Oct. 15, 2004

(51) Int. Cl. H01L 21/265

(52) U.S. Cl. 438/520

(57) ABSTRACT

Methods of forming a microelectronic structure are described. Those methods comprise implanting a first concentration of a species into an active area with a first energy, wherein the species pre-damages a portion of the active area, and then implanting a second concentration of the species into the active area with a second energy, wherein the total concentration of the species does not substantially penetrate an underlying channel region.

### FIELD OF THE INVENTION

The present invention generally relates to the field of microelectronic devices, and more particularly to methods of optimizing implantation conditions while minimizing channeling effects.

### BACK GROUND OF THE INVENTION

Integrated circuits form the basis for many electronic systems. An integrated circuit may include a vast number of transistors and other circuit elements that may be formed on a single semiconductor wafer or chip and may be interconnected to implement a desired function. Transistors may comprise active areas, such as a gate, a source and/or a drain, which are electrically conductive areas within the transistor, as are well known in the art.

FIG. 6 depicts an example of a transistor structure 600 of the prior art. An active area 602 of the transistor structure 600 may be exposed to a silicide metallization process (not shown) in order to reduce the contact resistance, for example, of the transistor structure 600, as is well known in the art. Prior to silicidation, an amorphizing implant process 610 may be applied to the active area 602, in which an implant species 611, such as germanium or arsenic, for example, may be implanted into the active area 602 of the transistor structure 600. The amorphizing implant may serve to contain the depth of a metal film formed during the silicidation process, as is well known in the art.

As transistor dimensions are increasingly scaled down, the thickness 612 of the active area 602 can become comparable and/or smaller than a penetration depth 614 of the implant species 611 of the amorphizing implant 610. Consequently, the amorphizing implant may penetrate through the active area 602 and into underlying regions of the transistor, such a gate oxide region 604 and/or a channel region 606.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1d represent methods of forming structures according to an embodiment of the present invention.

FIG. 2 represents a structure according to an embodiment of the present invention.

FIG. 3 represents a flow chart of a method according to another embodiment of the present invention.

FIGS. 4a-4b represent structures according to another embodiment of the present invention.

FIG. 5 represents a system according to another embodiment of the present invention.

FIG. 6 represents a structure according to the Prior Art.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic device are described. Those methods comprise implanting a first concentration of a species into an active area with a first energy, wherein the species pre-damages a portion of the active area, and then implanting a second concentration of the species into the active area with a second energy, wherein the total concentration of the species does not substantially penetrate an underlying channel region. By utilizing a first energy which is lower than the second energy, the range of the first implant may be shallower than the range of the second implant. In this manner, the deleterious channeling effects may be substantially reduced and/or eliminated. Thus, improved device performance, as well as decreased active area thickness, may be achieved.

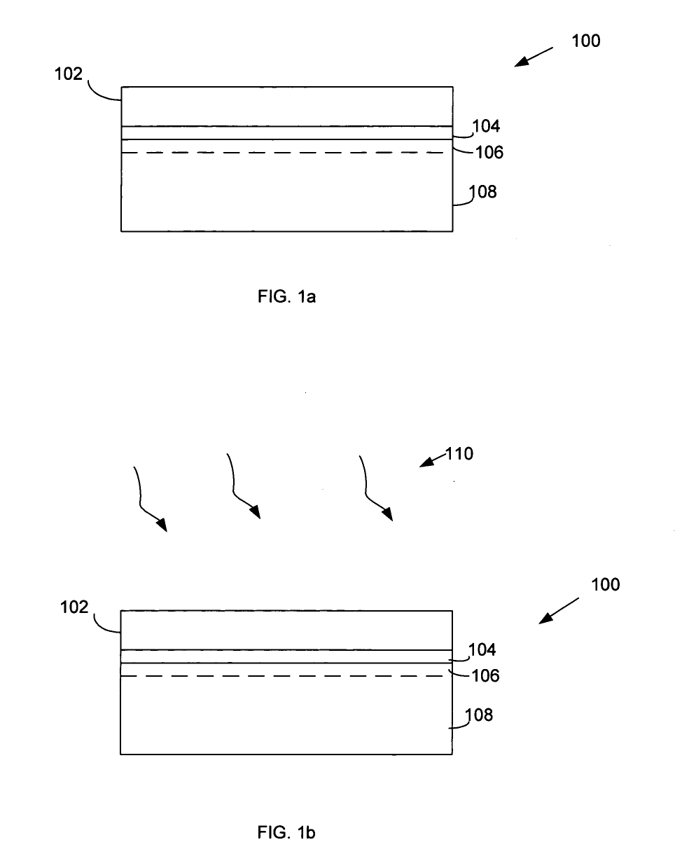

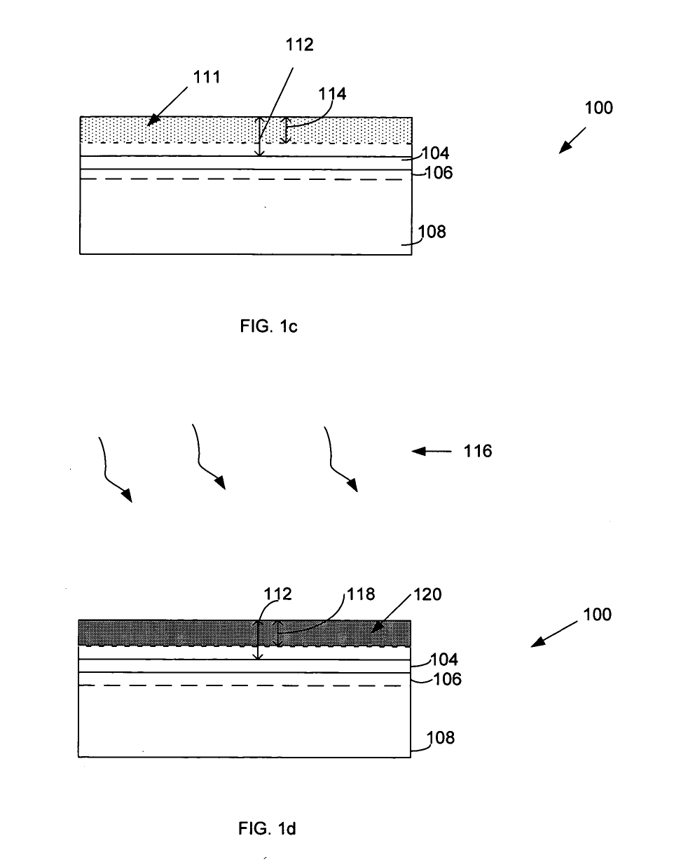

FIGS. 1a-1d illustrate an embodiment of a method of forming a microelectronic structure, such as a transistor structure, for example. FIG. 1a illustrates a microelectronic structure 100. The microelectronic structure 100 may comprise an active area 102. The active area 102 may comprise an electrically active area of the microelectronic structure 100, such as but not limited to a gate, a source and/or a drain, as are known in the art. The active area 102 may comprise a material such as polysilicon, for example. The active area 102 may comprise an active area depth 112. In one embodiment, the active area 102 may comprise an active area depth 112 of about 800 angstroms or less. In another embodiment, the active area 102 may comprise an active area depth 112 of about 1500 angstroms or less.

The microelectronic structure 100 may further comprise an oxide region 104, for example in the case when the active area 102 comprises a gate, the oxide region 104 may comprise a gate oxide, as is known in the art. The gate oxide may comprise a thickness below about 30 angstroms, for example, and may comprise silicon dioxide. The microelectronic structure 100 may further comprise an underlying channel region 106, wherein electrical current may flow, as is known in the art. The microelectronic structure 100 may also comprise a substrate region 108, which may comprise silicon, silicon-on-insulator, silicon on diamond, or combinations thereof, by illustration and not limitation.

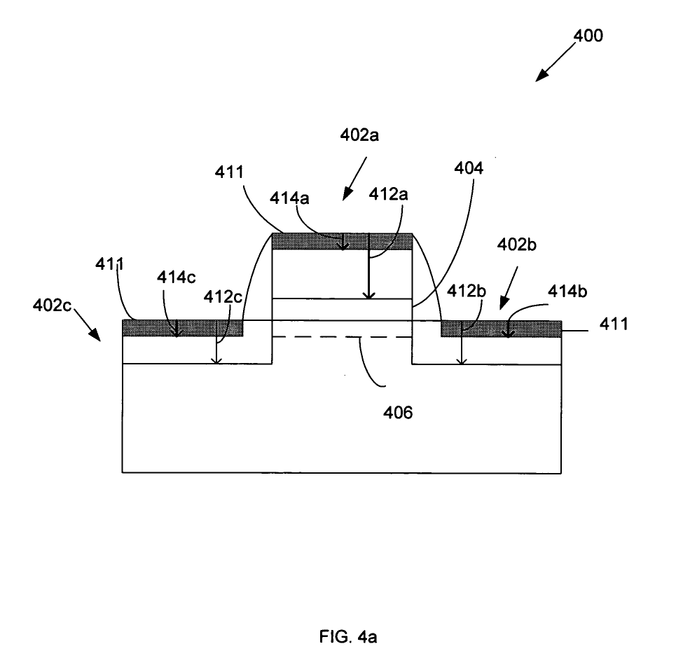

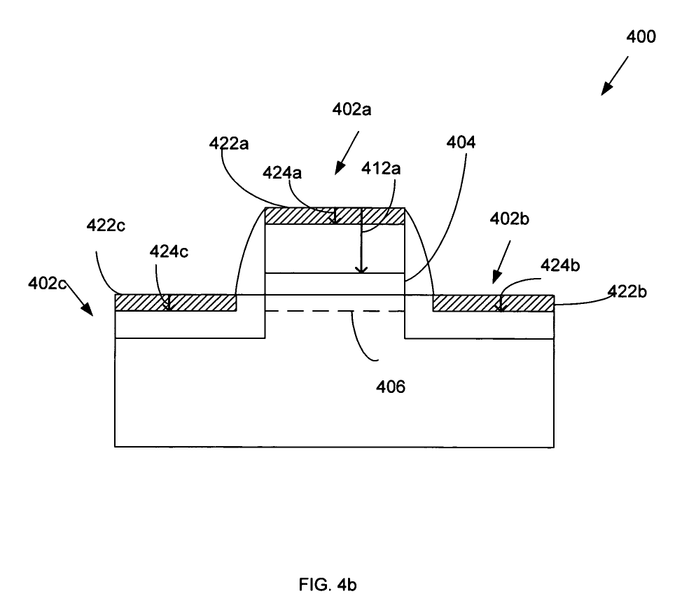

A first amorphizing implant 110 may be applied to the microelectronic structure 100 utilizing various process tools as are well known in the art (FIG. 1b). In one embodiment, the first amorphizing implant 110 may comprise a species 111 (FIG. 1c), such as but not limited to germanium, boron, silicon, argon, and combinations thereof, for example. The first amorphizing implant 110 may pre-damage a portion of the active area 102. The pre-damaging of a portion of the active area 102 may comprise damaging of a portion of the internal crystal structure of the active area 102, which in one embodiment may comprise silicon, for example. The pre-damaging of a portion of the active area 102 facilitates the formation on and/or within the portion of the active area 102 of a subsequently formed silicide layer 422 (FIG. 4b), to be described further herein.

The first amorphizing implant 110 may comprise a first energy and a first dose of the species 111. The magnitude of the first energy and the first dose of the first amorphizing implant 110 may be chosen such that the first energy and the first dose of the first amorphizing implant 110 may determine a first penetration depth 114 of the implant species 111. The first penetration depth 114 may comprise the depth, or distance, that the species 111 of the first amorphization implant 110 may penetrate into the active area 102. In other words, one skilled in the art will recognize that the first penetration depth 114 may comprise the implant tail of the implant species 111 as implanted into the active area 102.

In one embodiment, the first dose may range from about 6 keV to about 8 keV, with an implant species comprising germanium. The first dose may range from about 6E14 to about 8E14, with a first penetration depth 114 comprising about 600 angstroms. The implantation of the species 111 into the active area 102 with the first energy and first dose may introduce a first concentration of the implant species 111 into the active area. In one embodiment, the first concentration of the species 111 may generally be less than that required to achieve a desired amount of amorphization of the active area 102, thus a second amorphizing implant 116 (FIG. 1d) may be applied to the active area 102 to achieve a desired amount of amorphization.

The first penetration depth 114 of the first amorphizing implant 110 into the active area 102 may serve to control a final penetration depth 118 of the second amorphizing implant 116 into the active area 102. That is, because the first amorphizing implant 110 may pre-damage the active area 102, the second amorphizing implant 116 is blocked in a sense, from penetrating substantially further into the active area 102 than the first penetration depth 114. Thus the channeling effect, i.e., the penetration from the second amorphizing implant 116 of the species 111 beyond the active area depth 112 into the oxide region 104 and/or underlying channel region 106 may be significantly reduced and/or eliminated by the pre-damage from the first amorphizing implant 110. In one embodiment, the ratio of the final penetration depth 118 to the active area depth 112 may be less than about 2 to 3 (2:3).

The second amorphizing implant 116 may comprise a second energy and a second dose. In one embodiment the second energy may range from about 13 keV to about 17 keV, but may be of greater magnitude than the first energy. The second dose may range from about 3E14 to about 7E14, but may be of greater magnitude than the first dose of the first amorphizing implant 110. The second amorphizing implant 116 of the species 111 may introduce a second concentration of the species 111 into the active area 102.

A total concentration 120 of the species 111 (which represents the combined amount of species 111 implanted from the first amorphizing implant 110 and the second amorphizing implant 116) may be chosen, by varying the amount of the first and second implant doses and energies such that the total concentration 120 of the implant species 111 achieves the desired amount, or depth, of amorphization within the active area 102. Thus, by utilizing a first amorphizing implant 110 combined with a second amorphizing implant 116, wherein the initial amorphizing implant 110 is at a lower energy and dose than the second amorphizing implant 116, a desired total concentration of implant species 111 may be achieved. In one embodiment, a desired amorphizing depth may be achieved which may result in a shallower final penetration depth 118 than if simply one implant (applied at the dose and energy to achieve the desired total concentration) had been applied to the active area 102.

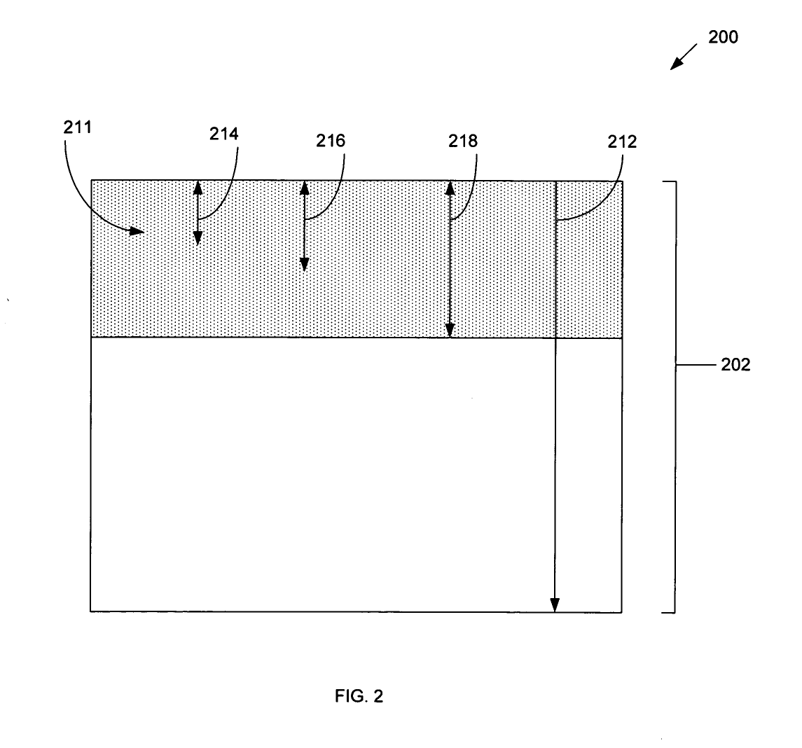

In another embodiment (FIG. 2), successive amorphizing implants, each of which comprise an implant tail, or penetration depth into an active area 202 (similar to the active area 102 of FIG. 1a, for example) of a microelectronic structure 200, may be applied to the active area 202. For example, a first penetration depth 214, a second penetration depth 216 and a third penetration depth 218 may arise from a first, a second and a third amorphizing implant (not shown) of a species 211, the species 211 comprising germanium, arsenic, boron, silicon and/or combinations thereof, for example. The doses and energies of the second and third amorphizing implants may be greater than the dose and energy of the first amorphizing implant. It will be understood that the magnitudes of the successive doses, energies and concentrations of the implant species will vary depending upon the particular application. The number of successive amorphizing implants will vary according to the particular application as well.

In one embodiment, the third penetration depth 218, which may represent the highest energy amorphizing implant, may comprise the longest penetration depth amongst the first, second and third penetration depths 214, 216, 218. Because the first penetration depth 214 of the first amorphizing implant effectively reduces and/or blocks the channeling effect of the second and third amorphizing implants, the third penetration depth 218 is substantially less than the active area depth 212.

In one embodiment, the ratio of the third penetration depth 218 to the active area depth 212 may be less than about 2 to 3 (2:3). Thus, by utilizing multiple amorphizing implants, wherein the initial amorphizing implant is at a lower energy and dose than successive amorphizing implants, a desired total concentration of implant species and a desired amorphizing depth may be achieved, without incurring the deleterious channeling effects of the species 211. In one embodiment, a desired amorphizing depth may be achieved which may result in a shallower final penetration depth (after successive implants are applied) than if simply one implant (applied at the dose and energy to achieve the desired total concentration) had been applied to the active area 202. Consequently, transistor device performance, such as a higher drive current, may be greatly enhanced, in some embodiments.

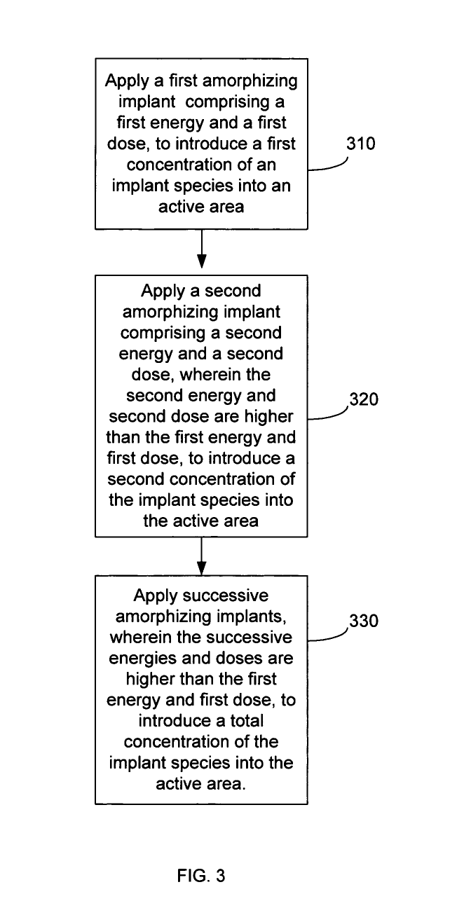

FIG. 3 depicts a flow chart of yet another embodiment of the present invention. At step 310, a first amorphizing implant is applied, comprising a first energy and a first dose, to introduce a first concentration of an implant species into an active area. At step 320, a second amorphizing implant is applied comprising a second energy and a second dose, wherein the second energy and second dose are higher than the first energy and first dose, to introduce a second concentration of the implant species into the active area. At step 330, successive amorphizing implants are applied, wherein the successive energies and doses of each successive amorphizing implant are higher than the first energy and first dose. In this manner, a tail, i.e., a penetration depth, (similar to the penetration depths depicted in FIG. 2, for example), of an amorphizing implant comprising the highest energy in relation to multiple amorphizing implants that have been applied to an active area, may be reduced.

FIG. 4a depicts structures that may be formed in accordance with another embodiment of the present invention. A microelectronic structure 400, such as a transistor structure, may comprise active areas 402a, 402b, 402c, which may in one embodiment comprise a gate, a source and a drain respectively. The active areas 402a, 402b and 402c may comprise active area depths 412a, 412b, and 412c respectively. The microelectronic structure 400 may further comprise a gate oxide 404 and a channel region 406, as are well known in the art. The microelectronic structure 400 may include a species 411 such as germanium, arsenic, boron and/or silicon or combinations thereof, which may be implanted during an amorphizing implant (not shown). The species 411 may penetrate into the active areas 402a, 402b, 402c corresponding to the penetration depths 414a, 414b, 414c.

A silicidation process may be performed on the microelectronic structure 400, as is well known in the art (FIG. 4b). In one embodiment, the silicidation process may comprise reacting a noble and/or refractory metal, such as nickel, cobalt or titanium, with the active areas 402a, 402b, 402c, which in this embodiment may comprise silicon. A silicide layer 422a, 422b, 422c may then form over and into the active areas 402a, 402b, 402c respectively. An advantage of the methods of the present invention is that by tailoring the penetration depths 414a, 414b, 414c of the species 411, the depths 424a, 424b, 424c of the of the silicide layers 422a, 422b, 422c may be controlled according to the particular application. Another advantage is that the damage to the crystalline structure of the active areas 402a, 402b, 402c species 411 may be confined to the region to be silicided, which may result in reduced species 411 deactivation, as is well known in the art.

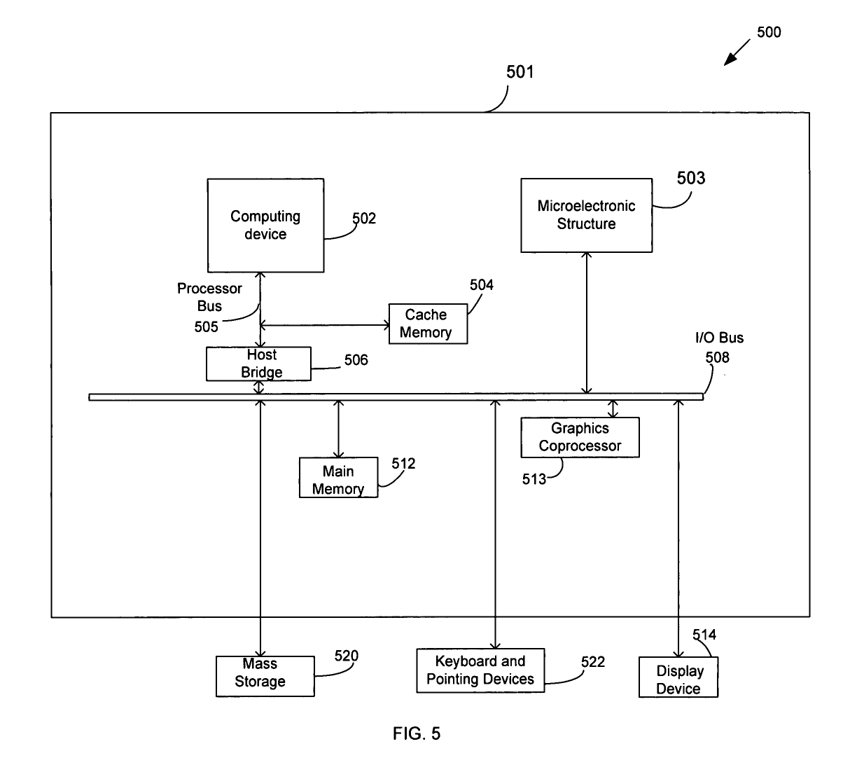

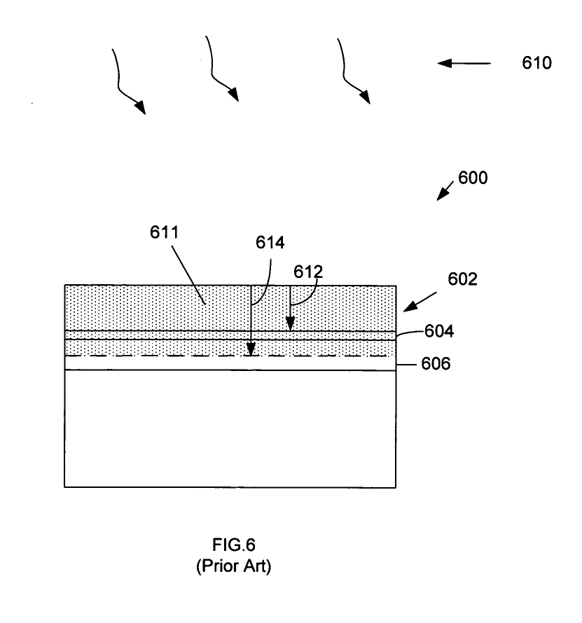

FIG. 5 is a diagram illustrating an exemplary system capable of being operated with methods for fabricating a microelectronic structure, such as the microelectronic structures 100, 200 and 400 of FIGS. 1, 2 and 4 respectively. It will be understood that the present embodiment is but one of many possible systems in which the microelectronic structures of the present invention may be used. The system 500 may be used, for example, to execute the processing by various processing tools, such as implanting tools, as are well known in the art, for the methods described herein.

In the system 500, a microelectronic structure 503 may be communicatively coupled to a printed circuit board (PCB) 501 by way of an I/O bus 508. The communicative coupling of the microelectronic structure 503 may be established by physical means, such as through the use of a package and/or a socket connection to mount the microelectronic structure 503 to the PCB 501 (for example by the use of a chip package and/or a land grid array socket). The microelectronic structure 503 may also be communicatively coupled to the PCB 501 through various wireless means (for example, without the use of a physical connection to the PCB), as are well known in the art.

The system 500 may include a computing device 502, such as a processor, and a cache memory 504 communicatively coupled to each other through a processor bus 505. The processor bus 505 and the I/O bus 508 may be bridged by a host bridge 506. Communicatively coupled to the I/O bus 508 and also to the microelectronic structure 503 may be a main memory 512. Examples of the main memory 512 may include, but are not limited to, static random access memory (SRAM) and/or dynamic random access memory (DRAM). The system 500 may also include a graphics coprocessor 513, however incorporation of the graphics coprocessor 513 into the system 500 is not necessary to the operation of the system 500. Coupled to the I/O bus 508 may be a display device 514, a mass storage device 520, and keyboard and pointing devices 522.

These elements perform their conventional functions well known in the art. In particular, mass storage 520 may be used to provide long-term storage for the executable instructions for a method for forming microelectronic structures in accordance with embodiments of the present invention, whereas main memory 512 may be used to store on a shorter term basis the executable instructions of a method for forming microelectronic structures in accordance with embodiments of the present invention during execution by computing device 502. In addition, the instructions may be stored on other machine readable mediums accessible by the system, such as compact disk read only memories (CD-ROMs), digital versatile disks (DVDs), and floppy disks, for example. In one embodiment, main memory 512 may supply the computing device 502 (which may be a processor, for example) with the executable instructions for execution.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that various microelectronic structures, such as transistor structures, are well known in the art. Therefore, the Figures provided herein illustrate only portions of an exemplary microelectronic device that pertains to the practice of the present invention. Thus the present invention is not limited to the structures described herein.

What is claimed is:

1. A method of forming a structure comprising;
implanting a first concentration of a species into an active area with a first energy, wherein the species pre-damages a portion of the active area; and
implanting a second concentration of the species into the active area with a second energy, wherein the total concentration of the species does not substantially penetrate an underlying channel region.

2. The method of claim 1 wherein implanting the first concentration of species comprises implanting a species selected from the group consisting of germanium, boron, arsenic, silicon and combinations thereof.

3. The method of claim 1 further comprising forming a silicide layer on the active area.

4. The method of claim 3 wherein forming the silicide layer comprises forming the silicide layer by reacting the active area with a silicide material selected from the group consisting of nickel, refractory metals, noble metals and combinations thereof.

5. The method of claim 1 wherein implanting the first concentration of the species into the active area comprises implanting the first concentration of the species into at least one of a gate, a source and a drain.

6. The method of claim 5 wherein implanting the first concentration of the species into the active area comprises implanting the first concentration of the species into an active area comprising polysilicon.

7. The method of claim 1 wherein the total concentration of the species does not substantially penetrate the underlying channel region comprises the ratio of a final penetration depth of the species to the depth of the active area is approximately less than 2 to 3.

8. The method of claim 1 wherein implanting the second concentration of the species into the active area with the second energy comprises implanting the second concentration of the species into the active area with the second energy, wherein the second energy is greater than the first energy.

9. The method of claim 1 further comprising implanting successive concentrations of the species into the active area, wherein each successive implant energy is greater than the first implant energy.

10. The method of claim 1 further comprising wherein the species amorphizes a portion of the active area.

11. The method of claim 1 wherein the second concentration of the species is substantially prevented from penetrating the underlying channel region by the pre-damaging of the first amorphizing implant.

12. The method of claim 1 wherein implanting a first concentration of a species into an active area with a first energy comprises implanting a first concentration of a species into an active area comprising a depth of about 800 angstroms with a first energy comprising about 6 keV to about 8 keV.

13. The method of claim 12 wherein implanting a second concentration of the species into the active area with a second energy comprises implanting a second concentration of the species into the active area with a second energy from about 13 keV to about 17 keV, wherein the final penetration depth comprises less than about 600 angstroms.

14. A structure comprising:
An active area comprising an amorphizing species, wherein the ratio of a final penetration depth of the amorphizing species to the depth of the active area is approximately less than 2 to 3.

15. The structure of claim 14 wherein the active area comprises polysilicon.

16. The structure of claim 14 wherein the amorphizing species is selected from the group consisting of germanium, silicon, arsenic and boron and combinations thereof.

17. The structure of claim 14 wherein the depth of the active area is about 800 angstroms or less.

18. The structure of claim 17 wherein the final penetration depth is less than about 600 angstroms.

19. A structure comprising:
An active area comprising a plurality of penetration depths of an amorphizing species, wherein the ratio of the longest penetration depth to the depth of the active area is approximately less than 2 to 3.

20. The structure of claim 19 wherein the amorphizing species is selected from the group consisting of germanium, silicon, arsenic, boron and combinations thereof.

21. The structure of claim 19 wherein the active area comprises at least one of a gate, a source and a drain.

22. The structure of claim 19 wherein the depth of the active area is about 1500 angstroms or less.

23. The structure of claim 19 wherein the longest penetration depth is less than about 600 angstroms.

24. A system comprising:
a package comprising an active area, wherein the active area comprises an amorphizing species wherein the ratio of a penetration depth of the amorphizing species to the depth of the active area is approximately less than 2 to 3;
a bus communicatively coupled to the gate structure; and
a DRAM communicatively coupled to the bus.

25. The system of claim 24 wherein the active area comprise at least one of a gate, a source and a drain.

26. The system of claim 24 wherein the active area comprises polysilicon.

27. The system of claim 24 wherein the depth of active area is less than about 800 angstroms, and wherein the final penetration depth is less than about 600 angstroms.

28. The system of claim 24 wherein the amorphizing species is selected from the group consisting of germanium, silicon, arsenic, boron and combinations thereof.

29. A machine accessible media having associated instructions which, when accessed by a processor, result in:
implanting a first concentration of a species into an active area with a first energy, wherein the species pre-damages a portion of the active area; and
implanting a second concentration of the species into the active area with a second energy, wherein the total concentration of the species does not substantially penetrate an underlying channel region.

30. The media of claim 29 wherein the ratio of a penetration depth of the amorphizing species to the depth of the active area is approximately less than about 2 to 3.

31. The media of claim 29 wherein the amorphizing species is selected from the group consisting of germanium, silicon, arsenic, boron and combinations thereof.

32. The media of claim 29 wherein the depth of active area is less than about 800 angstroms, and wherein the final penetration depth is less than about 600 angstroms.
